(19) United States
(12) Patent Application Publication
(10) Pub. No.: US 2012/0055544 A1
(43) Pub. Date: Mar. 8, 2012

(54) SOLAR CELL AND METHOD OF MANUFACTURING THE SAME

(76) Inventors: Dong-Gi AHN, Yongin-si (KR); Kwang Soo Huh, Yongin-si (KR); Hyong Jin Park, Yongin-si (KR); In-ki Kim, Yongin-si (KR); Su Jin Kim, Yongin-si (KR)

(21) Appl. No.: 13/222,433

(22) Filed: Aug. 31, 2011

(30) Foreign Application Priority Data
Sep. 3, 2010 (KR) 10-2010-0086642

(51) Int. Cl. H01L 31/0224; H01L 31/18

(52) U.S. Cl. 136/256; 438/93; 257/E31.126

(57) ABSTRACT

A solar cell with improved energy efficiency is presented. The solar cell includes a substrate having a plurality of cell areas separated by a cell separation area, back electrodes spaced apart from each other by a gap, a light absorbing layer, a transparent electrode layer, and a buffer layer. Each of the back electrodes is disposed over neighboring cell areas and a cell separation area. The light absorbing layer is disposed on the back electrodes and in the gap to absorb incident light. A contact hole extends through the light absorbing layer to a portion of the back electrodes. The transparent electrode layer disposed on the light absorbing layer connects to the back electrodes through the contact hole. The buffer layer is disposed between the light absorbing layer and the transparent electrode layer to cover upper and side surfaces of the light absorbing layer.

### CROSS-REFERENCE TO RELATED APPLICATION

This application claims priority from Korean Patent Application No. 2010-86642 filed on Sep. 3, 2010, the content of which are herein incorporated by reference in its entirety.

### BACKGROUND

1. Field of Disclosure

The present invention relates to a solar cell and a method of manufacturing the same. More particularly, the present invention relates to a solar cell having improved energy efficiency and a method of manufacturing the solar cell.

2. Description of the Related Art

A solar cell is used to convert solar energy into electricity. In general, a solar cell is manufactured by a p-n junction formed by a p-type semiconductor and an n-type semiconductor. When light having energy that is greater than an energy band gap of the semiconductor is incident on the solar cell, electron-hole pairs are generated. Electrons in the electron-hole pairs move to the n-type semiconductor and holes in the electron-hole pairs move to the p-type semiconductor due to an electric field generated at the p-n junction. Accordingly, when loads are connected to both ends of the solar cell, a current starts to flow through the solar cell.

When a lattice constant difference between the p-type semiconductor and the n-type semiconductor and an energy band-gap difference between the p-type semiconductor and the n-type semiconductor increase, a buffer layer is required between the p-type semiconductor and the n-type semiconductor to improve junction properties between the p-type and n-type semiconductors.

### SUMMARY

In one aspect, the present invention provides a solar cell having improved energy converting efficiency.

In another aspect, the present invention provides a method of manufacturing the solar cell.

According to one aspect of the invention, a solar cell includes a substrate, a plurality of back electrodes, a light absorbing layer having a contact hole, a transparent electrode layer, and a buffer layer.

The substrate includes a plurality of cell areas and a cell separation area disposed between neighboring cell areas. The back electrodes are formed spaced apart from each other by a gap, and each of the back electrodes is disposed on the neighboring cell areas and the cell separation area therebetween. The light absorbing layer is disposed on the back electrodes and in the gap between the back electrodes, the light absorbing layer absorbing incident light. The transparent electrode layer is disposed on the light absorbing layer and connected to the back electrodes through the contact hole that extends through the light absorbing layer. The buffer layer is disposed between the light absorbing layer and the transparent electrode layer to cover upper and side surfaces of the light absorbing layer. The side surface of the light absorbing layer defines the contact hole.

According to another aspect of the invention, a method of manufacturing a solar cell is provided as follows.

A substrate including a plurality of cell areas and a cell separation area disposed between neighboring cell areas is prepared, and a plurality of back electrodes is formed. The back electrodes are spaced apart from each other by a gap, and each of the back electrodes is disposed on the neighboring cell areas and the cell separation area. A light absorbing layer is formed on the back electrodes and in the gap, and a portion of the light absorbing layer is removed to form a contact hole that extends to a portion of the back electrodes. A buffer layer is formed on upper and side surfaces of the light absorbing layer, and in the contact hole. The buffer layer disposed at a base of the contact hole is removed while the buffer layer disposed on the upper and side surfaces of the light absorbing layer is left. A transparent electrode layer is formed on the buffer layer and in the contact holes.

According to the above, a shunt resistance of the solar cell may be increased and the defect density of the solar cell may be decreased, thereby reducing the recombination ratio of the hole-electron pairs and improving the energy converting efficiency.

### BRIEF DESCRIPTION OF THE DRAWINGS

The above and other advantages of the present invention will become readily apparent by reference to the following detailed description when considered in conjunction with the accompanying drawings wherein:

FIG. 1 is a cross-sectional view of a solar cell according to an exemplary embodiment of the present invention;

FIG. 2 is a cross-sectional view of a solar cell according to another exemplary embodiment of the present invention;

FIGS. 3A to 3H are views illustrating a method of manufacturing the solar cell of FIG. 1; and

FIGS. 4A to 4I are views illustrating a method of manufacturing the solar cell of FIG. 2.

### DETAILED DESCRIPTION

It will be understood that when an element or layer is referred to as being “on”, “connected to” or “coupled to” another element or layer, it can be directly on, connected to or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the invention. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

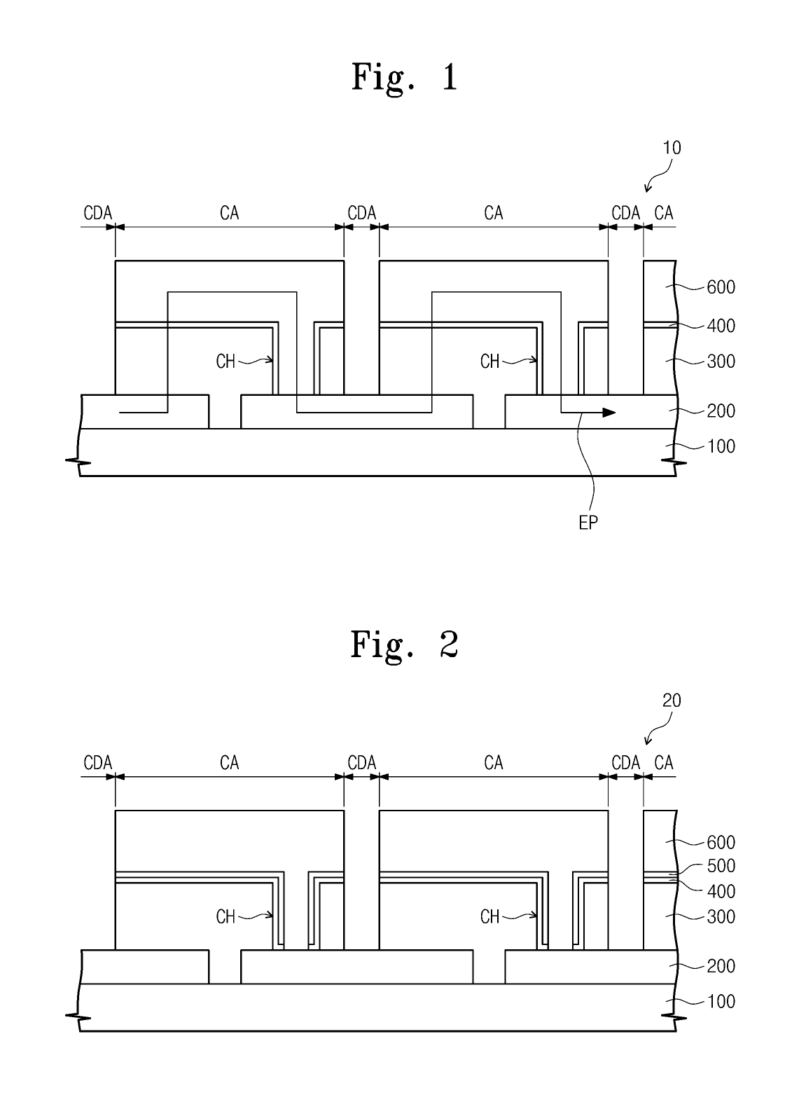

FIG. 1 is a cross-sectional view of a solar cell according to an exemplary embodiment of the present invention. For convenience of explanation, two cells in the solar cell are shown because the cells in the solar cell have substantially the same structure and function.

Referring to FIG. 1, a solar cell 10 includes a substrate 100, back electrodes 200, a light absorbing layer 300, a buffer layer 400, and a transparent electrode layer 600.

The substrate 100 includes a plurality of cell areas CA and a cell separation area CDA disposed between two neighboring cell areas CA. The substrate 100 may be a ceramic substrate, a plastic substrate, or a metal substrate. In detail, the substrate 100 may include ceramic materials such as silicon, glass, aluminum oxide, etc. In addition, the substrate 100 may be a soda lime glass substrate. As used herein, “neighboring” cell areas includes but is not limited to immediately adjacent cell areas.

The back electrodes 200 are disposed on the substrate 100 and spaced apart from each other to form a gap. Each of the back electrodes 200 is disposed on two neighboring cell areas CA and the cell separation area CDA between them.

The back electrodes 200 may include at least one material selected from the group consisting of molybdenum (Mo), aluminum (Al), titanium (Ti), copper (Cu), tungsten (W), gold (Au), platinum (Pt), silver (Ag), and chromium (Cr). Each of the back electrodes 200 may include two or more layers, which may be the same as each other or different from each other. Particularly, in the case where the back electrodes 200 are formed of molybdenum (Mo), the back electrodes 200 may be formed by a sputtering process using a molybdenum target or a chemical vapor deposition process. Although not shown in FIG. 1, the back electrodes 200 may be arranged in a strip shape or a matrix shape when viewed in a plan view.

The light absorbing layer 300 is disposed on the back electrodes 200 and the substrate 100 in the cell areas CAs to absorb light. The light absorbing layer 300 is provided with a contact hole CH formed therethrough, extending to a portion of the back electrodes 200. Although not shown in FIG. 1, the contact hole CH may have various cross-sectional shapes such as a polygonal shape (e.g., a square shape, a rectangular shape), a spherical shape, or an oval shape.

As shown in FIG. 1, the contact hole CH does not overlap the gap between neighboring back electrodes 200. In the embodiment of FIG. 1, the contact hole CH is spaced apart from the gap between two neighboring electrodes 200.

The light absorbing layer 300 may include a chemical semiconductor compound. In detail, the light absorbing layer 300 may include one or more of copper-indium-gallium-selenium (CIGS) compound, copper-indium-selenium (CIS) compound, copper-gallium-selenium (CGS) compound, and cadmium telluride (CdTe) compound.

More particularly, the light absorbing layer 300 may include at least one material selected from the group consisting of CdTe, CuInSe₂, Cu(In,Ga)Se₂, Cu(In,Ga)(Se,S)₂, Ag(InGa)Se₂, Cu(In,Al)Se₂, and CiGaSe₂.

In the case that the CIGS compound is used as the light absorbing layer 300, the CIGS compound may be formed by a co-evaporation method or a two-step processing method.

The co-evaporation method substantially simultaneously evaporates four individual sources for the CIGS compound, e.g., copper (Cu), indium (In), gallium (Ga), and selenium (Se), to form a thin film on a substrate under the high temperature.

According to the two-step processing method, precursor thin films are formed on a substrate through a sputtering process using copper (Cu), indium (In), gallium (Ga), and selenium (Se) as sputtering targets thereof. Then, the substrate on which the precursor thin films are formed is heat-treated under a hydride atmosphere (e.g., H₂Se, H₂S), thereby controlling the composition ratio of copper (Cu), indium (In), gallium (Ga), and selenium (Se).

In the case that the CIS compound or the CIG compound is used as the light absorbing layer 300, the light absorbing layer 300 may be formed by a sputtering process using a copper and indium target or a copper and gallium target and by performing a selenization process.

In the case where soda lime glass is used as the substrate 100, sodium existing in the substrate 100 may diffuse to the light absorbing layer 300 through the back electrodes 200 during the sputtering process and the selenization process.

The buffer layer 400 is disposed on the light absorbing layer 300 and the back electrodes 200 corresponding to the cell areas CA. In detail, the buffer layer 400 may cover the upper surface of the light absorbing layer 300 and the side surface, which defines the contact hole CH, of the light absorbing layer 300. In the embodiment of FIG. 1, the buffer layer 400 is not formed on the cell separation area CDA.

The buffer layer 400 has an energy band-gap between an energy band-gap of the light absorbing layer 300 and an energy band-gap of the transparent electrode layer 600 to ease the lattice constant difference between the light absorbing layer 300 and the transparent electrode layer 600. For instance, the buffer layer 400 may include at least one material selected from the group consisting of ZnS, CdS, Zn(O,S,OH), In(OH)xSy, ZnInxSey, ZnSe, InS, and ZnSO.

In detail, the light absorbing layer 300 has a band-gap energy of about 1 eV to about 1.8 eV, the buffer layer 400 has a band-gap energy of about 2.2 eV to about 2.4 eV, and the transparent electrode layer 600 has a band-gap energy of about 3.1 eV to about 3.3 eV.

The transparent electrode layer 600 is formed of a transparent conductive oxide material having superior transmittance and conductivity such that the light transmits through the light absorbing layer 300 and the transparent electrode layer 600 serves as an electrode layer. For example, the transparent electrode layer 600 may include at least one material selected from the group consisting of ZnO:Al, ZnO:B, ITO, IZO, ZnO, GaZO, ZnMgO, and SnO₂.

Although not shown in FIG. 1, a reflection preventing layer (not shown) may be disposed on the transparent electrode layer 600. When the reflection preventing layer is formed on the transparent electrode layer 600 to reduce the amount of light reflected by the transparent electrode layer 600, the energy converting efficiency of the solar cell 10 may be improved. The reflection preventing layer may be formed of MgF₂.

Hereinafter, the energy converting efficiency of the solar cell 10 will be described in detail with reference to FIG. 1.

When light passes through the transparent electrode layer 600 and reaches the light absorbing layer 300, electron-hole pairs are generated. The light absorbing layer 300 serves as the p-type semiconductor and the buffer layer 400 and the transparent electrode layer 600 serves as the n-type semiconductor. Accordingly, the electrons move to the buffer 400 and the transparent electrode layer 600 and the holes move to the light absorbing layer 300. Thus, the solar cell 10 converts the solar energy to electric energy.

According to a moving path (EP) of the electrons shown in FIG. 1, the cell in the solar cell disposed in each cell area CA is connected to an adjacent cell thereto in series, so the electrons move along the cells in the solar cell.

The buffer layer 400 reduces defect density occurring at the interface between the light absorbing layer 300 and the transparent electrode layer 600 to improve the energy converting efficiency of the solar cell 10. Particularly, when defect density at the interface is relatively large, recombination ratio of the hole-electron pairs becomes high, thereby causing deterioration in the energy converting efficiency of the solar cell. Thus, the buffer layer 400 disposed between the light absorbing layer 300 and the transparent electrode layer 600 reduces the defect density at the interface, to thereby improve the energy converting efficiency of the solar cell 10.

FIG. 2 is a cross-sectional view showing a solar cell according to another exemplary embodiment of the present invention. In FIG. 2, the same reference numerals denote the same elements in FIG. 1, and thus redundant descriptions of the same elements will be omitted.

Referring to FIG. 2, the solar cell 20 includes a substrate 100, back electrodes 200, a light absorbing layer 300, a buffer layer 400, an intrinsic layer 500, and a transparent electrode layer 600.

The intrinsic layer 500 is disposed on the buffer layer 400 to cover the buffer layer 400. In detail, the intrinsic layer 500 is disposed to cover the upper surface of the buffer layer 400 and the side surface, which defines the contact hole CH, of the buffer layer 400.

The intrinsic layer 500 is formed of a transparent material such that light transmitted through the transparent electrode layer 600 reaches the light absorbing layer 300. The intrinsic layer 500 may be formed of ZnO. In particular, the intrinsic layer 500 may be formed of intrinsic ZnO that is not doped by a group-III dopant or a group-V dopant. In addition, the intrinsic layer 500 may have a band-gap energy of about 3.1 eV to about 3.3 eV.

The intrinsic layer 500 may be formed by a sputtering method using ZnO target or by a chemical vapor deposition method.

The transparent electrode layer 600 is disposed on the intrinsic layer 500 corresponding to the cell areas CA. In addition, the transparent electrode layer 600 may connect to the back electrodes 200 through the contact hole CH.

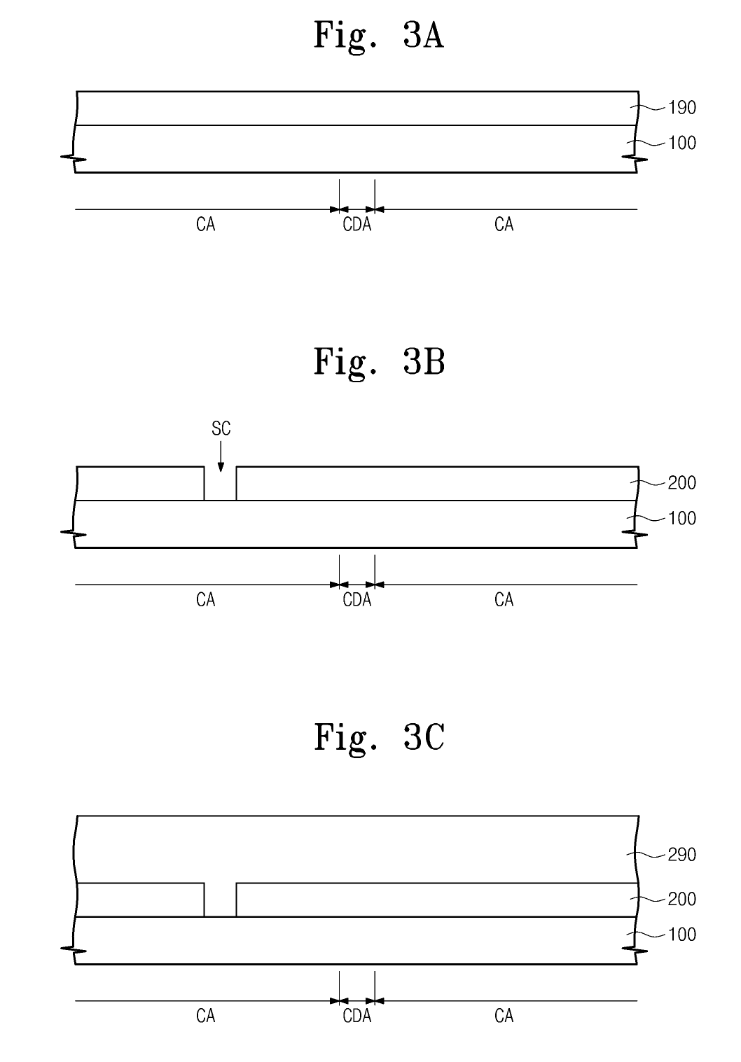

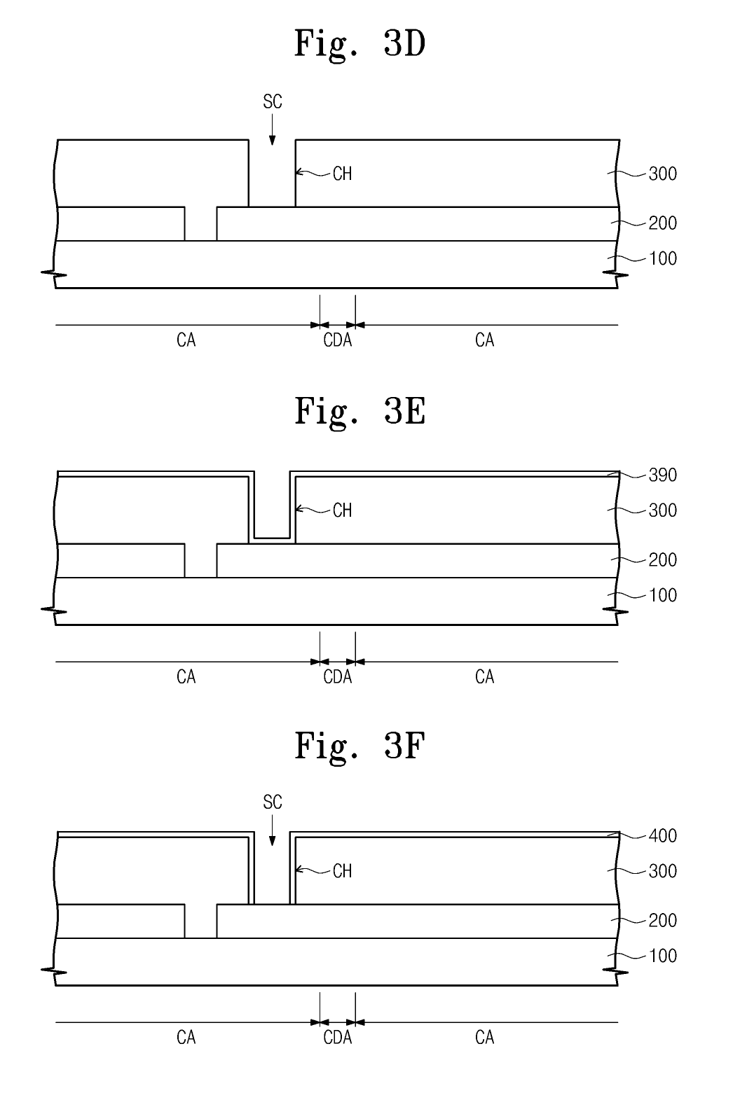

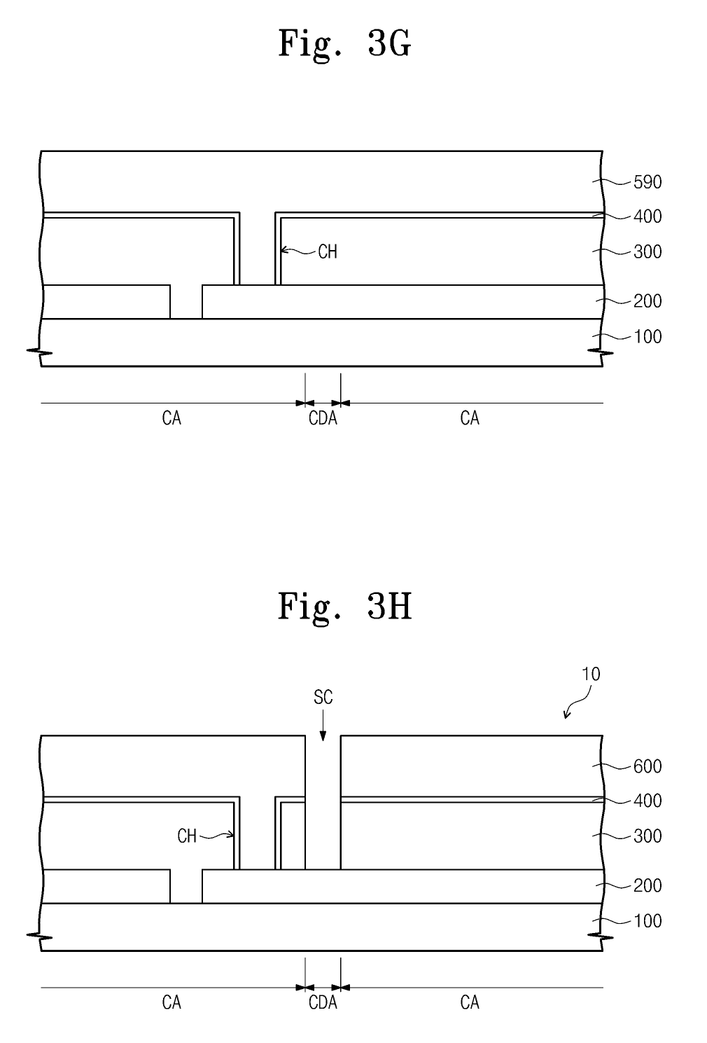

FIGS. 3A to 3H are views illustrating a method of manufacturing the solar cell of FIG. 1. For convenience of explanation, two cell areas CA and a cell separation area CDA disposed between the two cell areas are shown in FIGS. 3A to 3H.

Referring to FIGS. 3A to 3H, the substrate 100 including the cell areas CA and the cell separation areas CDA each disposed between two neighboring cell areas CA is prepared. Then, a back electrode layer 190 is formed on the substrate 100. As described above, the back electrode layer 190 may be formed by the sputtering method or the chemical vapor deposition method.

Then, a scribing process SC is applied to the back electrode layer 190 to form the back electrodes 200. The scribing process SC may be a laser scribing process or a mechanical scribing process. Next, a light absorbing layer 290 is formed on the back electrodes 200. As described above, the light absorbing layer 290 may be formed by the sputtering method. Particularly, in the case that the light absorbing layer 290 includes the CIGS compound, the light absorbing layer 290 may be formed by various methods, such as co-evaporation method, two-step processing method, etc.

Referring to FIG. 3D, the scribing process SC is applied to the light absorbing layer 290 to form the contact hole CH through which a portion of the back electrodes 200 is exposed. The scribing process SC may be a laser scribing process or a mechanical scribing process.

As shown in FIG. 3E, a buffer layer 390 is formed to cover the upper surface of the light absorbing layer 300, the side surface of the light absorbing layer 300 that defines the contact hole CH, and the portion of the back electrodes 200 that forms a base of the contact hole CH. The buffer layer 390 may be formed by the sputtering method or the chemical vapor deposition method.

Then, referring to FIG. 3F, the buffer layer formed on the back electrodes 200 is partially removed by a scribing process SC. The buffer layer formed on the upper and side surfaces of the light absorbing layer 300 is not removed during this process. Hence, a portion of the back electrodes 200 is exposed through the contact hole CH.

Referring to FIG. 3G, a transparent electrode layer 590 is formed on the buffer layer 400 and the portion of the back electrodes 200 that is exposed through the contact hole CH. Although not shown in figures, the reflection preventing layer may be further formed on the transparent electrode layer 590.

As shown in FIG. 3H, portions of the transparent electrode layer 590, the buffer layer 400, and the light absorbing layer 300 are removed by a scribing process SC to form the cell separation area CDA. The cell separation area CDA separates the solar cells from each other. The scribing process SC may be a laser scribing process or a mechanical scribing process.

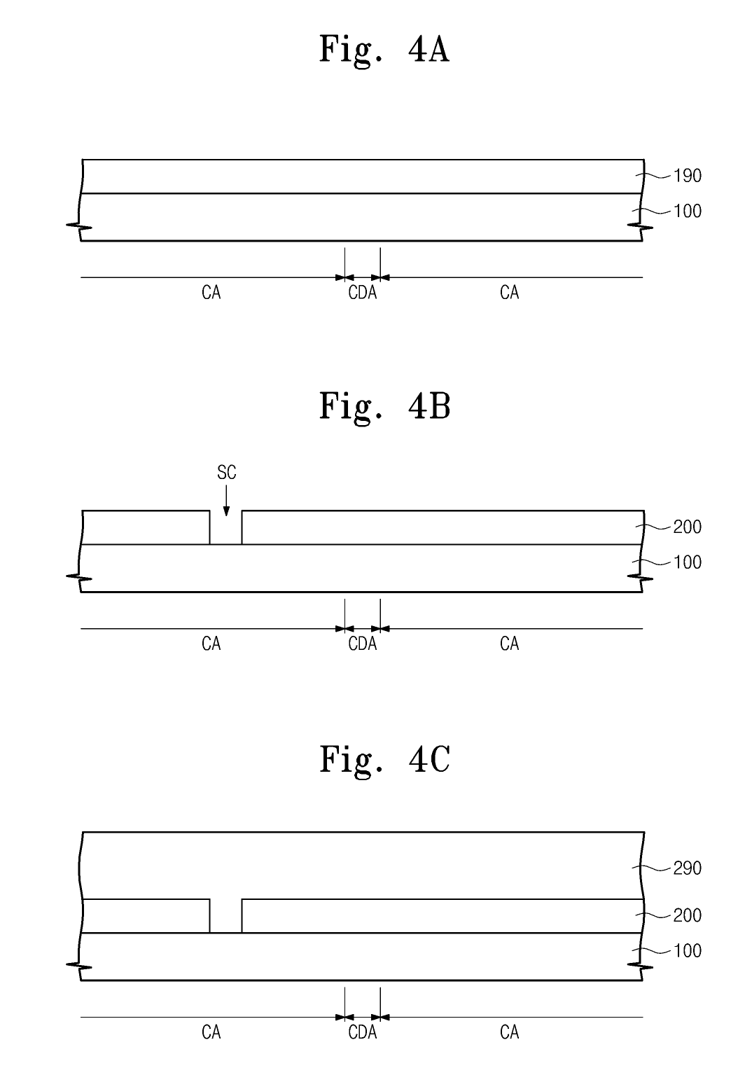

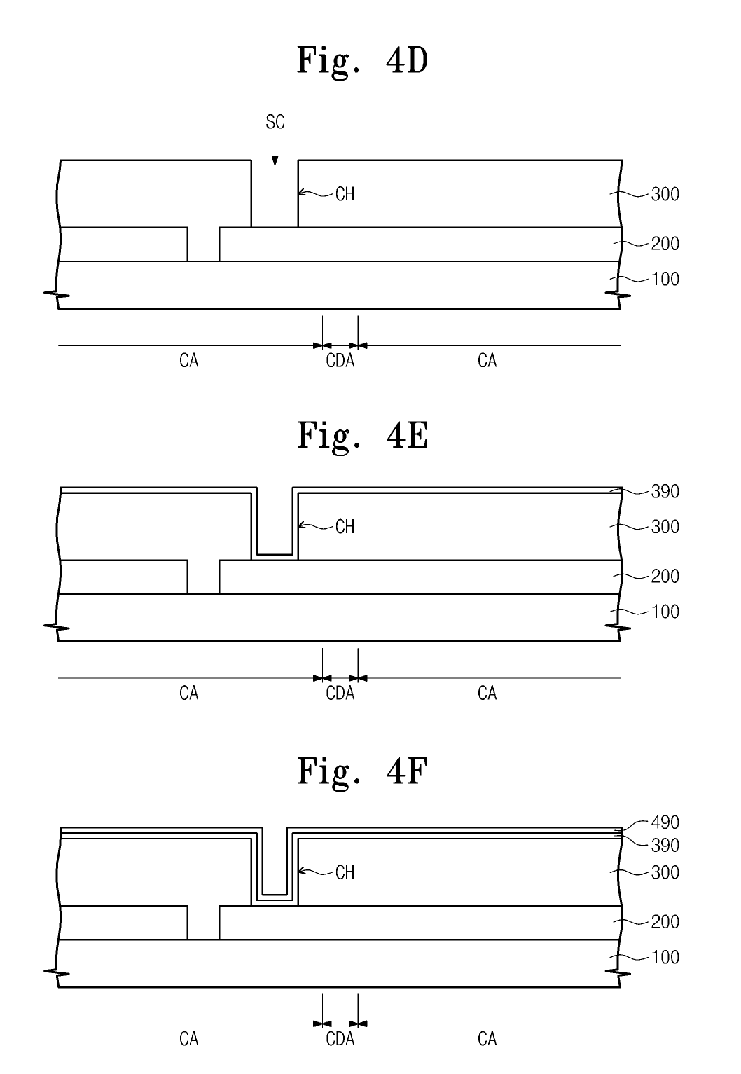

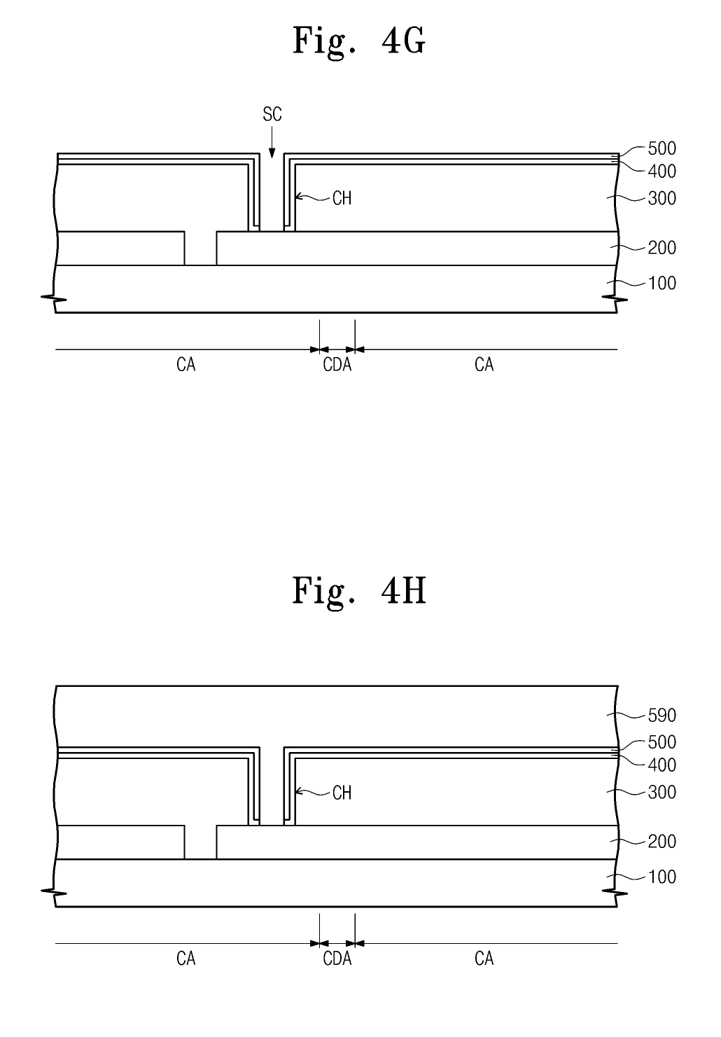

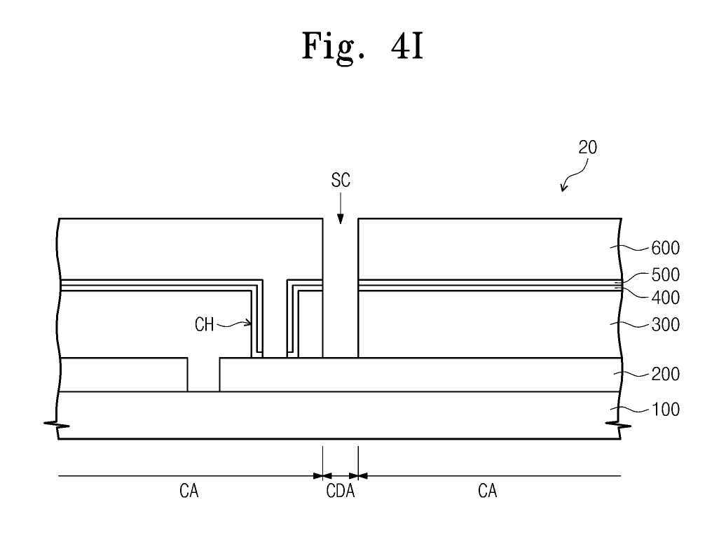

FIGS. 4A to 4I are views illustrating a method of manufacturing the solar cell of FIG. 2. In FIGS. 4A to 4I, the same reference numerals denote the same elements as in FIGS. 3A to 3I, and thus redundant description of the same elements will be omitted.

Referring to FIGS. 4A to 4I, a buffer layer 390 is formed on the light absorbing layer 300 and an intrinsic layer 490 is formed on the buffer layer 390. As described above, the intrinsic layer 490 may be formed by a sputtering method using ZnO target or a chemical vapor deposition method.

Then, as shown in FIG. 4G, the buffer layer and the intrinsic layer formed on the back electrodes 200 may be removed by a scribing process SC. The buffer layer 390 and the intrinsic layer 490 formed on the upper and side surfaces of the light absorbing layer 300 are not removed during this process, so that a portion of the back electrodes 200 is exposed through the contact hole CH formed through the light absorbing layer 300. The scribing process SC may be a laser scribing process or a mechanical scribing process.

Although not shown in the figures, the scribing process may be separately applied to each of the buffer layer 400 and the intrinsic layer 500. In other words, after forming the buffer layer 390, the buffer layer 390 formed on the back electrodes 200 is removed by the scribing process except for the portion formed on the upper and side surfaces of the light absorbing layer 300. Then, after the intrinsic layer 490 is formed on the portion of the back electrodes 200 at the base of the contact hole CH and on the buffer layer 400, the intrinsic layer 490 formed at the base of the contact hole CH may be removed by the scribing process except for the intrinsic layer 490 formed on the buffer layer 400.

Referring to FIG. 4H, a transparent electrode layer 590 is formed on the intrinsic layer 500 and the back electrodes 200 exposed through the contact hole CH. Although not shown in FIG. 4H, a reflection preventing layer may also be formed on the transparent electrode layer 590.

As shown in FIG. 4I, portions of the transparent electrode layer 590, the buffer layer 400, the intrinsic layer 500, and the light absorbing layer 300 are removed by a scribing process SC to form the cell separation area CDA. The cell separation area CDA separates the solar cells from each other. The scribing process SC may be a laser scribing process or a mechanical scribing process.

According to FIGS. 3A to 3H and 4A to 4I, each of the solar cells 10 and 20 may be formed by performing the scribing process SC four times including the scribing process SC performed between forming the light absorbing layer 300 and forming the buffer layer 400. Since the scribing process SC is performed before forming the buffer layer 400 and after forming the light absorbing layer 300, the buffer layer 400 may be formed to cover the side surface of the light absorbing layer 300 in the contact hole CH. In addition, the buffer layer 400 and the intrinsic layer 500 may be formed to cover the side surface of the light absorbing layer 300.

Accordingly, the buffer layer 400 or the intrinsic layer 500 may be formed to cover both of the upper and side surfaces of the light absorbing layer 300 in the solar cells 10 and 20. This configuration increases a shunt resistance of the solar cell and decreases the defect density of the solar cell, thereby reducing the recombination ratio of the hole-electron pairs and improving the energy converting efficiency.

Although the exemplary embodiments of the present invention have been described, it is understood that the present invention should not be limited to these exemplary embodiments but various changes and modifications can be made by one ordinary skilled in the art within the spirit and scope of the present invention as hereinafter claimed.

What is claimed is:

1. A solar cell comprising:
a substrate including a plurality of cell areas and a cell separation area disposed between neighboring cell areas;
a plurality of back electrodes spaced apart from each other to form a gap, each of the back electrodes being disposed on the neighboring cell areas and the cell separation area between the neighboring cell areas;
a light absorbing layer disposed on the back electrodes and in the gap between the back electrodes, the light absorbing layer absorbing incident light;
a contact hole extending through the light absorbing layer to the back electrodes;
a transparent electrode layer disposed on the light absorbing layer and connected to the back electrodes through the contact hole; and
a buffer layer disposed between the light absorbing layer and the transparent electrode layer to cover upper and side surfaces of the light absorbing layer, the side surface of the light absorbing layer being a sidewall of the contact hole.

2. The solar cell of claim 1, further comprising an intrinsic layer disposed to cover an upper surface of the buffer layer and a side surface of the buffer layer in the contact hole.

3. The solar cell of claim 1, wherein the contact hole is spaced apart from the cell separation area.

4. The solar cell of claim 1, wherein the buffer layer has a band-gap energy between a band-gap energy of the light absorbing layer and a band-gap energy of the transparent electrode layer.

5. The solar cell of claim 1, wherein the light absorbing layer comprises at least one material selected from the group consisting of copper, indium, gallium, and selenium.

6. The solar cell of claim 1, wherein the transparent electrode layer comprises a transparent conductive oxide material.

7. The solar cell of claim 6, wherein the transparent conductive oxide material comprises at least one material selected from the group consisting of ZnO:Al, ZnO:B, ZnO:F, ITO, and IZO.

8. A method of manufacturing a solar cell, comprising:
preparing a substrate including a plurality of cell areas and a cell separation area disposed between neighboring cell areas;
forming a plurality of back electrodes spaced apart from each other by a gap, each of the back electrodes being on the neighboring cell areas and the cell separation area between the neighboring cell areas;
forming a light absorbing layer on the back electrodes and in the gap;
removing a portion of the light absorbing layer to form a contact hole extending to a portion of the back electrodes;
forming a buffer layer on upper and side surfaces of the light absorbing layer and in the contact hole; and
removing the buffer layer disposed at a base of the contact hole to expose the back electrodes through the contact hole while leaving the buffer layer on the upper and side surfaces of the light absorbing layer; and
forming a transparent electrode layer on the buffer layer and in the contact hole.

9. The method of claim 8, further comprising:
forming an intrinsic layer on the buffer layer; and
removing the intrinsic layer formed on a base of the contact hole while leaving the intrinsic layer formed on the upper and side surfaces of the light absorbing layer.

10. The method of claim 9, wherein the transparent electrode layer is formed on the intrinsic layer and the exposed back electrodes.

11. The method of claim 8, wherein the contact hole is spaced apart from the cell separation area.

12. The method of claim 8, wherein the buffer layer has a band-gap energy between a band-gap energy of the light absorbing layer and a band-gap energy of the transparent electrode layer.

13. The method of claim 8, further comprising removing a portion of each of the light absorbing layer, the buffer layer, and the transparent electrode layer in the cell separation area.

14. The method of claim 8, wherein the forming of the back electrodes comprises:
forming a back electrode layer on the substrate; and
patterning the back electrode layer to form the back electrodes.

15. The method of claim 8, wherein the light absorbing layer comprises at least one material selected from the group consisting of copper, indium, gallium, and selenium.

16. The method of claim 8, wherein the transparent electrode layer comprises a transparent conductive oxide material.
